(19) United States
(12) Patent Application Publication
(10) Pub. No.: US 2020/0258566 A1
(43) Pub. Date: Aug. 13, 2020

(54) REFRESH RATE MANAGEMENT FOR MEMORY

(71) Applicant: Micron Technology, Inc., Boise, ID (US)

(72) Inventors: Scott E. Schaefer, Boise, ID (US); Aaron P. Boehm, Boise, ID (US)

(21) Appl. No.: 16/786,737

(22) Filed: Feb. 10, 2020

Related U.S. Application Data
(60) Provisional application No. 62/804,270, filed on Feb. 12, 2019.

(51) Int. Cl. G11C 11/406

(52) U.S. Cl. CPC G11C 11/40626; G11C 2211/406; G11C 11/40615

(57) ABSTRACT

Methods, systems, and devices for refresh rate management for a memory device are described. A memory device may receive refresh commands for a memory array (e.g., from a host device). The memory device may determine that a refresh rate associated with the refresh commands is below a threshold, and the threshold may be based on a condition of the memory array. The memory device may transmit signaling (e.g., to a host device) indicating that the refresh rate associated with the refresh commands is below the threshold. Additionally or alternatively, the memory device may switch from a first mode of operation to a second mode of operation based on determining that the refresh rate associated with the refresh commands is below the threshold. The second mode of operation may restrict access to at least a portion of the memory array. Additionally or alternatively, the second mode of operation may include a self-refresh mode.

### CROSS REFERENCE

The present application for patent claims the benefit of U.S. Provisional Patent Application No. 62/804,270, by SCHAEFER et al., entitled “REFRESH RATE MANAGEMENT FOR MEMORY,” filed Feb. 12, 2019, which is assigned to the assignee hereof, and which is expressly incorporated by reference in its entirety herein.

### BACKGROUND

The following relates generally to a system that includes at least one memory device and more specifically to refresh rate management for a memory device.

Memory devices are widely used to store information in various electronic devices such as computers, wireless communication devices, cameras, digital displays, and the like. Information is stored by programing different states of a memory device. For example, binary devices most often store one of two states, often denoted by a logic 1 or a logic 0. In other devices, more than two states may be stored. To access the stored information, a component of the device may read, or sense, at least one stored state in the memory device. To store information, a component of the device may write, or program, the state in the memory device.

Various types of memory devices exist, including magnetic hard disks, Random Access Memory (RAM), Read-Only Memory (ROM), Dynamic RAM (DRAM), Static RAM (SRAM), synchronous dynamic RAM (SDRAM), ferroelectric RAM (FeRAM), magnetic RAM (MRAM), resistive RAM (RRAM), flash memory, phase change memory (PCM), and others. Memory devices may be volatile or non-volatile. Non-volatile memory, e.g., FeRAM, may maintain their stored logic state for extended periods of time even in the absence of an external power source. Volatile memory devices, e.g., DRAM and SRAM, may lose their stored state over time unless they are connected to an external power source. Dynamic memory devices, e.g., DRAM, may also use periodic refreshing to maintain the memory cell states.

For some types of memory (e.g., Dynamic Random Access Memory (DRAM) or other volatile types of memory), logic states stored by memory cells may need to be occasionally (e.g., periodically) refreshed. Further, in some cases, the frequency or rate with which refresh is initiated may be related to the temperature of a memory device. Improving memory devices, generally, may include increasing memory cell density, increasing read/write speeds, increasing reliability, increasing data retention, reducing power consumption, or reducing manufacturing costs, among other metrics.

### BRIEF DESCRIPTION OF THE DRAWINGS

FIG. 1 illustrates an example of a system that supports refresh rate management for a memory device as disclosed herein.

FIG. 2 illustrates an example of a memory die that supports refresh rate management for a memory device as disclosed herein.

FIG. 3 illustrates an example of a system that supports refresh rate management for a memory device as disclosed herein.

FIGS. 4 and 5 block diagram circuitry that support refresh rate management for a memory device as disclosed herein.

FIGS. 6 and 7 show block diagrams of circuitry that supports refresh rate management for a memory device as disclosed herein.

FIGS. 8 and 9 show flowcharts illustrating a method or methods that support supports refresh rate management for a memory device as disclosed herein.

### DETAILED DESCRIPTION

Memory devices may operate under various conditions as part of electronic apparatuses such as personal computers, wireless communication devices, servers, internet-of-things (IoT) devices, electronic components of automotive vehicles, and the like. In some cases, memory devices supporting applications for certain implementations (e.g., automotive vehicles, in some cases with autonomous or semi-autonomous driving capabilities) may be subject to increased reliability constraints. As such, memory devices (e.g., DRAM) for some applications may be expected to operate with a reliability subject to relatively higher industry specifications (e.g., higher reliability constraints).

Some memory cells, such as volatile memory cells, may exhibit deterioration (loss) of a stored logic state over time. For example, memory cells that utilize a capacitive storage element (e.g., DRAM memory cells) may lose a stored state or have a stored state change to a different state in the event of the capacitive storage element losing some amount of stored charge, such as due to charge leaking from a capacitor. Without intervention, such as refreshing the logic state by rewriting the memory cell (e.g., recharging the capacitive storage element), the logic state stored by the memory cell may be lost or corrupted. One solution is to refresh (rewrite) a memory array every so often (e.g., at periodic intervals), such as by writing to each memory cell in the array to the logic value stored by the memory cell at the time the memory cell is refreshed. The desirable rate of refresh for a memory array may depend on a variety of factors, including deterioration (e.g., leakage) rates of memory cells in the array and reliability criteria or constraints for the array. In some cases, (e.g., automotive applications), increased reliability of the memory array may be desired (e.g., for critical safety functions). Additionally or alternatively, deterioration rates may vary based on one or more operating conditions of the memory array (e.g., leakage rates for DRAM memory cells may increase with temperature, and automotive applications may subject the memory array to harsh (e.g., high) temperatures).

Techniques for improved refresh management for a memory device are described. In some cases, a memory device may receive refresh commands from a host device, and each refresh command may initiate one or more refresh cycles for a memory array. For example, memory cells within the memory array may be organized into multiple rows, and each refresh command from the host device may trigger a refresh of at least one row of memory cells. In some cases, a refresh command received by the memory device from the host device may specify the address of one row to be refreshed, and the memory device may determine one or more additional rows to also refresh in response to the command (e.g., using an on-chip counter to increment the row address specified by the refresh command so as to obtain one or more additional row addresses). The quantity of rows of memory cells refreshed by the memory device in response to one refresh command received from the host device may be referred to as a row multiplier or refresh multiplier.

The memory device may identify a refresh threshold (e.g., a target refresh rate or refresh parameter) for a memory array. For example, in some cases at least a minimum quantity of refresh commands must be received from the host device within a given time window in order to maintain the logic states stored within the array with acceptable reliability, and a refresh threshold may specify the duration of the time window, the minimum quantity of refresh commands for the time window, or both. In some cases, the refresh threshold may be based on a condition of the memory array, such a temperature of the memory device (which may be or may serve as a proxy for the temperature of the memory array). For example, as the temperature of the memory device increases, the minimum time window for receiving the quantity of refresh commands may decrease, thus increasing the refresh rate (e.g., memory device would receive the same quantity of refresh commands but in a shorter time interval).

In some cases, the memory device may determine that a refresh rate associated with refresh commands received from the host device does not satisfy (e.g., is below) the threshold. That is, the memory device may determine that the host device is not sending enough refresh commands within a given time window to maintain the logic states stored by the memory array with acceptable reliability. In some examples, the memory device may alert the host device that the refresh rate associated with the refresh commands in below a threshold. For example, the memory device may send signaling (e.g., a flag or other indication) to the host device to indicate that the host device is not sending enough refresh commands within a given time interval. In some cases, the signaling may indicate a minimum refresh rate for the memory array (e.g., may indicate the refresh threshold), which the memory device may have determined from the condition (e.g., temperature) of the host device.

In some cases, upon determining that the refresh rate of refresh commands received from the host device is below a threshold, the memory device may switch from a first mode of operation (e.g., a mode in which refresh of a memory array occurs based on refresh commands received from a host device, such as an auto-refresh mode) to a second mode of operation (e.g., a mode in which the memory device automatically refreshes the memory array independent of (e.g., without need or regard for) the receipt of any refresh commands, such as a self-refresh mode).

Additionally or alternatively, upon determining that the refresh rate of refresh commands received from the host device is below the threshold, the memory device may adjust a refresh multiplier. The memory device may alert the host device that is has entered the second mode of operation and continue functioning in the second mode of operation until it receives an acknowledgment from a host. In some, instances the memory device may restrict access to one or more portions of the array while in the second mode of operation.

Additionally or alternatively, the memory device may switch from the second mode of operation back to a first mode of operation after receiving an acknowledgement from the host device. The acknowledgement by the host device may include the host device indicating that it received the signaling from the memory device. The acknowledgement by the host device may include or be in addition to the host device indicating to the memory device (parroting back) the refresh threshold for the memory array, the host device sending a command for the memory device to allow access to one or more portions of the memory array (e.g., a command for the memory device to switch back to the first mode of operation), the host device sending refresh commands with a rate that satisfies the threshold, or the like. Upon returning to the first mode of operation, the memory device may monitor subsequent refresh commands from the host to determine whether the refresh commands continue to meet (satisfy) the threshold.

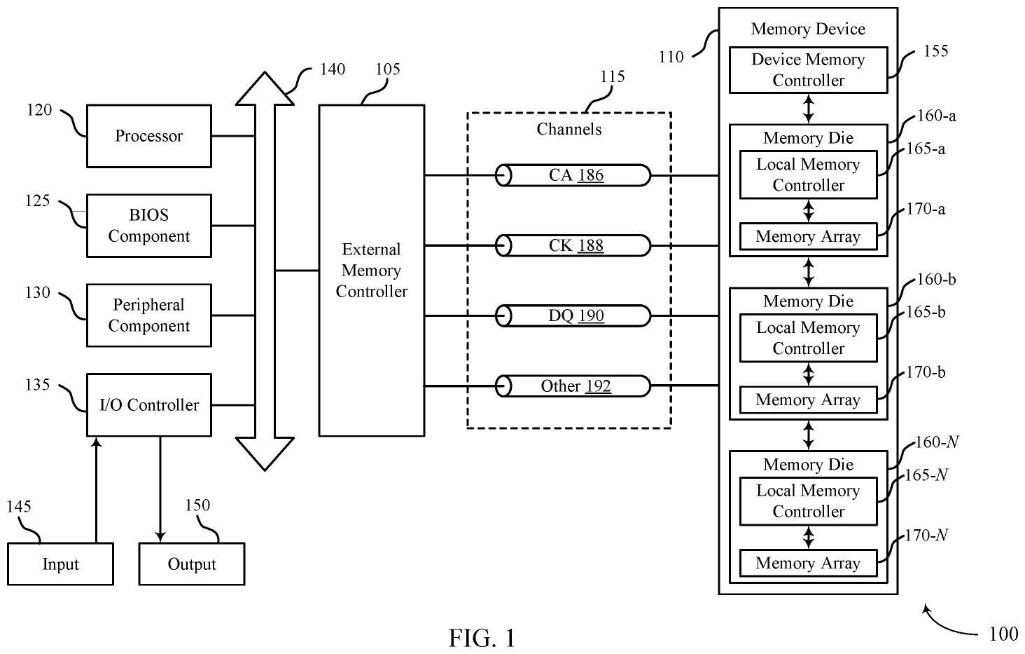

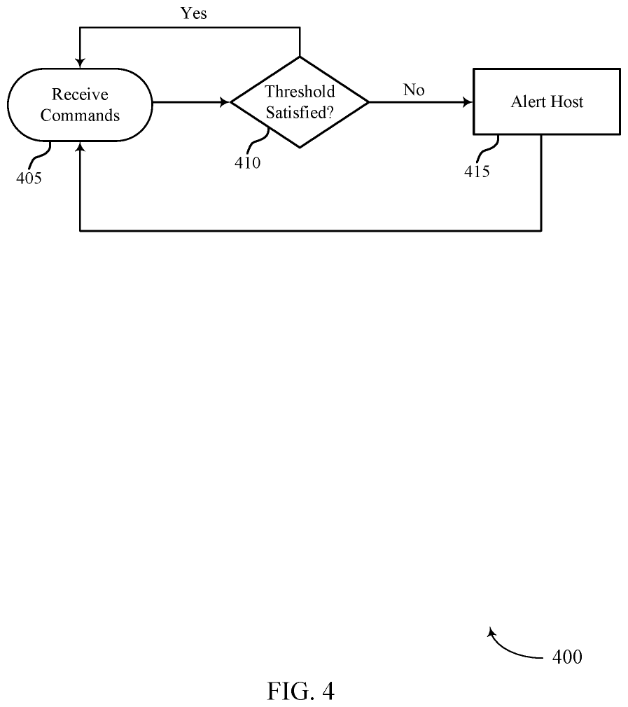

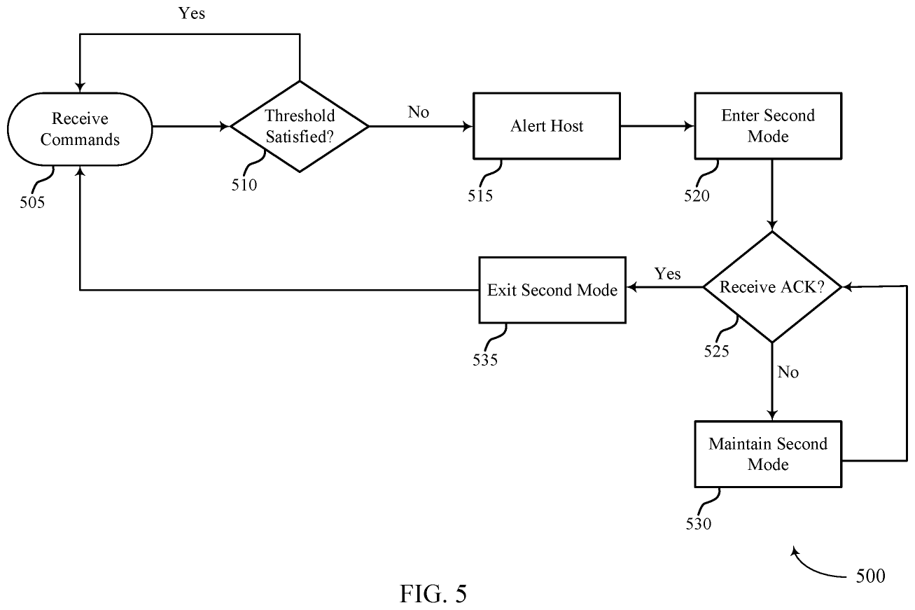

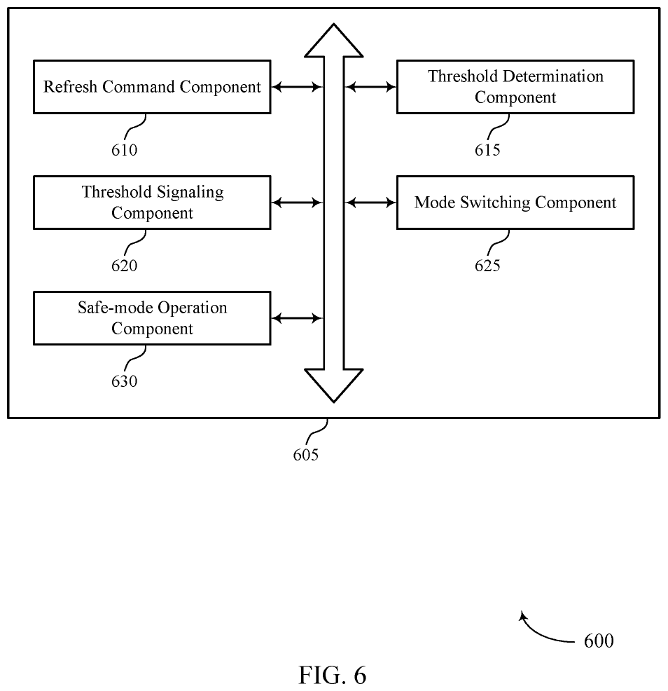

Features of the disclosure are initially described in the context of memory systems and devices with reference to FIGS. 1-3. Features of the disclosure are described in the context of process flows with reference to FIGS. 4-5. These and other features of the disclosure are further illustrated by and described with reference to apparatus diagrams and flowcharts in FIGS. 6-9 that relate to refresh rate management for a memory device.

FIG. 1 illustrates an example of a system 100 that utilizes one or more memory devices as disclosed herein. The system 100 may include an external memory controller 105, a memory device 110, and a plurality of channels 115 coupling the external memory controller 105 with the memory device 110. The system 100 may include one or more memory devices, but for ease of description the one or more memory devices may be described as a single memory device 110.

The system 100 may include aspects of an electronic device, such as a computing device, a mobile computing device, a wireless device, or a graphics processing device. In some cases, the system 100 is an automotive system, such as a vehicle control system, a fleet management system, a location tracking system, a navigation system, an infotainment system, or the like. The system 100 may be an example of a portable electronic device in other cases. The system 100 may be an example of a computer, a laptop computer, a tablet computer, a smartphone, a cellular phone, a wearable device, an internet-connected device, or the like. The memory device 110 may be component of the system configured to store data for one or more other components of the system 100. In some examples, the system 100 is configured for bi-directional wireless communication with other systems or devices using a base station or access point. In some examples, the system 100 is capable of machine-type communication (MTC), machine-to-machine (M2M) communication, or device-to-device (D2D) communication.

At least portions of the system 100 may be examples of a host device. Such a host device may be an example of a device that uses memory to execute processes such as a computing device, a mobile computing device, a wireless device, a graphics processing device (e.g., a graphics processing unit (GPU)), a computer, a laptop computer, a tablet computer, a smartphone, a cellular phone, a wearable device, an internet-connected device, some other stationary or portable electronic device, or the like. In some cases, the host device may refer to the hardware, firmware, software, or a combination thereof that implements the functions of the external memory controller 105. In some cases, the external memory controller 105 may be referred to as a host or host device.

In some cases, a memory device 110 may be an independent device or component that is configured to be in communication with other components of the system 100 and provide physical memory addresses/space to potentially be used or referenced by the system 100. In some examples, a memory device 110 may be configurable to work with at least one or a plurality of different types of systems 100. Signaling between the components of the system 100 and the memory device 110 may be operable to support modulation schemes to modulate the signals, different pin designs for communicating the signals, distinct packaging of the system 100 and the memory device 110, clock signaling and synchronization between the system 100 and the memory device 110, timing conventions, and/or other factors.

The memory device 110 may be configured to store data for the components of the system 100. In some cases, the memory device 110 may act as a slave-type device to the system 100 (e.g., responding to and executing commands provided by the system 100 through the external memory controller 105). Such commands may include an access command for an access operation, such as a write command for a write operation, a read command for a read operation, a refresh command for a refresh operation, or other commands. The memory device 110 may include two or more memory dice 160 (e.g., memory chips) to support a desired or specified capacity for data storage. A memory device 110 including two or more memory dice may be referred to as a multi-die memory or package (also referred to as multi-chip memory or package).

The system 100 may further include a processor 120, a basic input/output system (BIOS) component 125, one or more peripheral components 130, and an input/output (I/O) controller 135. The components of system 100 may be in electronic communication with one another using a bus 140.

The processor 120 may be configured to control at least portions of the system 100. The processor 120 may be a general-purpose processor, a digital signal processor (DSP), an application-specific integrated circuit (ASIC), a field-programmable gate array (FPGA) or other programmable logic device, discrete gate or transistor logic, discrete hardware components, or it may be a combination of these types of components. In such cases, the processor 120 may be an example of a central processing unit (CPU), a graphics processing unit (GPU), a general purpose GPU (GPGPU), or a system on a chip (SoC), among other examples.

The BIOS component 125 may be a software component that includes a BIOS operated as firmware, which may initialize and run various hardware components of the system 100. The BIOS component 125 may also manage data flow between the processor 120 and the various components of the system 100, e.g., the peripheral components 130, the I/O controller 135, etc. The BIOS component 125 may include a program or software stored in read-only memory (ROM), flash memory, or any other non-volatile memory.

The peripheral component(s) 130 may be any input device or output device, or an interface for such devices, that may be integrated into or with the system 100. Examples may include disk controllers, sound controller, graphics controller, Ethernet controller, modem, universal serial bus (USB) controller, a serial or parallel port, or peripheral card slots, such as peripheral component interconnect (PCI) or accelerated graphics port (AGP) slots. The peripheral component(s) 130 may be other components understood by those skilled in the art as peripherals.

The I/O controller 135 may manage data communication between the processor 120 and the peripheral component(s) 130, input devices 145, or output devices 150. The I/O controller 135 may manage peripherals that are not integrated into or with the system 100. In some cases, the I/O controller 135 may represent a physical connection or port to external peripheral components.

The input 145 may represent a device or signal external to the system 100 that provides information, signals, or data to the system 100 or its components. This may include a user interface or interface with or between other devices. In some cases, the input 145 may be a peripheral that interfaces with system 100 via one or more peripheral components 130 or may be managed by the I/O controller 135.

The output 150 may represent a device or signal external to the system 100 configured to receive an output from the system 100 or any of its components. Examples of the output 150 may include a display, audio speakers, a printing device, or another processor on printed circuit board, and so forth. In some cases, the output 150 may be a peripheral that interfaces with the system 100 via one or more peripheral components 130 or may be managed by the I/O controller 135.

The components of system 100 may be made up of general-purpose or special purpose circuitry designed to carry out their functions. This may include various circuit elements, for example, conductive lines, transistors, capacitors, inductors, resistors, amplifiers, or other active or passive elements, configured to carry out the functions described herein.

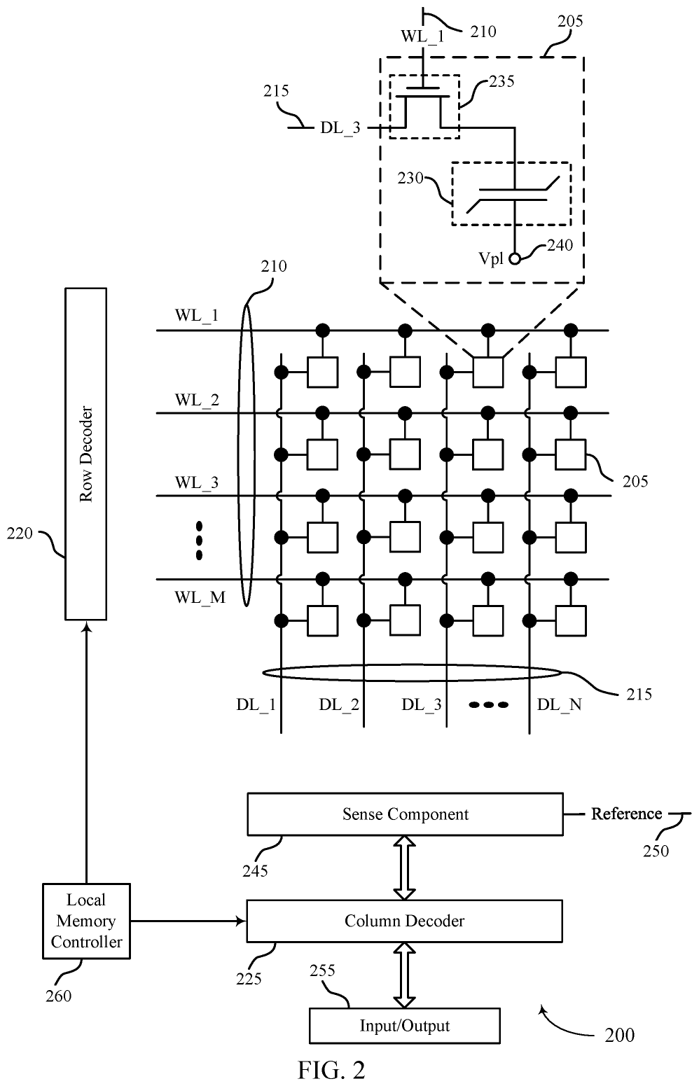

The memory device 110 may include a device memory controller 155 and one or more memory dice 160. Each memory die 160 may include a local memory controller 165 (e.g., local memory controller 165-a, local memory controller 165-b, and/or local memory controller 165-N) and a memory array 170 (e.g., memory array 170-a, memory array 170-b, and/or memory array 170-N). A memory array 170 may be a collection (e.g., a grid) of memory cells, with each memory cell being configured to store at least one bit of digital data. Features of memory arrays 170 and/or memory cells are described in more detail with reference to FIG. 2.

The memory device 110 may be an example of a two-dimensional (2D) array of memory cells or may be an example of a three-dimensional (3D) array of memory cells. For example, a 2D memory device may include a single memory die 160. A 3D memory device may include two or more memory dice 160 (e.g., memory die 160-a, memory die 160-b, and/or any quantity of memory dice 160-N). In a 3D memory device, a plurality of memory dice 160-N may be stacked on top of one another. In some cases, memory dice 160-N in a 3D memory device may be referred to as decks, levels, layers, or dies. A 3D memory device may include any quantity of stacked memory dice 160-N (e.g., two high, three high, four high, five high, six high, seven high, eight high). This may increase the quantity of memory cells that may be positioned on a substrate as compared with a single 2D memory device, which in turn may reduce production costs or increase the performance of the memory array, or both. In some 3D memory device, different decks may share at least one common access line such that some decks may share at least one of a word line, a digit line, and/or a plate line.

The device memory controller 155 may include circuits or components configured to control operation of the memory device 110. As such, the device memory controller 155 may include the hardware, firmware, and software that enables the memory device 110 to perform commands and may be configured to receive, transmit, or execute commands, data, or control information related to the memory device 110. The device memory controller 155 may be configured to communicate with the external memory controller 105, the one or more memory dice 160, or the processor 120. In some cases, the memory device 110 may receive data and/or commands from the external memory controller 105.

For example, the memory device 110 may receive a write command indicating that the memory device 110 is to store certain data on behalf of a component of the system 100 (e.g., the processor 120) or a read command indicating that the memory device 110 is to provide certain data stored in a memory die 160 to a component of the system 100 (e.g., the processor 120). In some cases, the device memory controller 155 may control operation of the memory device 110 described herein in conjunction with the local memory controller 165 of the memory die 160. Examples of the components included in the device memory controller 155 and/or the local memory controllers 165 may include receivers for demodulating signals received from the external memory controller 105, decoders for modulating and transmitting signals to the external memory controller 105, logic, decoders, amplifiers, filters, or the like.

The local memory controller 165 (e.g., local to a memory die 160) may be configured to control operations of the memory die 160. Also, the local memory controller 165 may be configured to communicate (e.g., receive and transmit data and/or commands) with the device memory controller 155. The local memory controller 165 may support the device memory controller 155 to control operation of the memory device 110 as described herein. In some cases, the memory device 110 does not include the device memory controller 155, and the local memory controller 165 or the external memory controller 105 may perform the various functions described herein. As such, the local memory controller 165 may be configured to communicate with the device memory controller 155, with other local memory controllers 165, or directly with the external memory controller 105 or the processor 120.

The external memory controller 105 may be configured to enable communication of information, data, and/or commands between components of the system 100 (e.g., the processor 120) and the memory device 110. The external memory controller 105 may act as a liaison between the components of the system 100 and the memory device 110 so that the components of the system 100 may not need to know the details of the memory device's operation. The components of the system 100 may present requests to the external memory controller 105 (e.g., read commands or write commands) that the external memory controller 105 satisfies. The external memory controller 105 may convert or translate communications exchanged between the components of the system 100 and the memory device 110. In some cases, the external memory controller 105 may include a system clock that generates a common (source) system clock signal. In some cases, the external memory controller 105 may include a common data clock that generates a common (source) data clock signal.

In some cases, the external memory controller 105 or other component of the system 100, or its functions described herein, may be implemented by the processor 120. For example, the external memory controller 105 may be hardware, firmware, or software, or some combination thereof implemented by the processor 120 or other component of the system 100. While the external memory controller 105 is depicted as being external to the memory device 110, in some cases, the external memory controller 105, or its functions described herein, may be implemented by a memory device 110. For example, the external memory controller 105 may be hardware, firmware, or software, or some combination thereof implemented by the device memory controller 155 or one or more local memory controllers 165. In some cases, the external memory controller 105 may be distributed across the processor 120 and the memory device 110 such that portions of the external memory controller 105 are implemented by the processor 120 and other portions are implemented by a device memory controller 155 or a local memory controller 165. Likewise, in some cases, one or more functions ascribed herein to the device memory controller 155 or local memory controller 165 may in some cases be performed by the external memory controller 105 (either separate from or as included in the processor 120).

The components of the system 100 may exchange information with the memory device 110 using a plurality of channels 115. In some examples, the channels 115 may enable communications between the external memory controller 105 and the memory device 110. Each channel 115 may include one or more signal paths or transmission mediums (e.g., conductors) between terminals associated with the components of system 100. For example, a channel 115 may include a first terminal including one or more pins or pads at external memory controller 105 and one or more pins or pads at the memory device 110. A pin may be an example of a conductive input or output point of a device of the system 100, and a pin may be configured to act as part of a channel. In some cases, a pin or pad of a terminal may be part of to a signal path of the channel 115. Additional signal paths may be coupled with a terminal of a channel for routing signals within a component of the system 100. For example, the memory device 110 may include signal paths (e.g., signal paths internal to the memory device 110 or its components, such as internal to a memory die 160) that route a signal from a terminal of a channel 115 to the various components of the memory device 110 (e.g., a device memory controller 155, memory dice 160, local memory controllers 165, memory arrays 170).

Channels 115 (and associated signal paths and terminals) may be dedicated to communicating specific types of information. In some cases, a channel 115 may be an aggregated channel and thus may include multiple individual channels. For example, a data channel 190 may be ×4 (e.g., including four signal paths), ×8 (e.g., including eight signal paths), ×16 (including sixteen signal paths), and so forth.

In some cases, the channels 115 may include one or more command and address (CA) channels 186. The CA channels 186 may be configured to communicate commands between the external memory controller 105 and the memory device 110 including control information associated with the commands (e.g., address information). For example, the CA channel 186 may include a read command with an address of the desired data. In some cases, the CA channels 186 may be registered on a rising clock signal edge and/or a falling clock signal edge. In some cases, a CA channel 186 may include eight or nine signal paths.

In some cases, the channels 115 may include one or more clock signal (CK) channels 188. The CK channels 188 may be configured to communicate one or more common clock signals between the external memory controller 105 and the memory device 110. Each clock signal may be configured to oscillate between a high state and a low state and coordinate the actions of the external memory controller 105 and the memory device 110. In some cases, the clock signal may be a differential output (e.g., a CK_t signal and a CK_c signal) and the signal paths of the CK channels 188 may be configured accordingly. In some cases, the clock signal may be single ended. In some cases, the clock signal may be a 1.5 GHz signal. A CK channel 188 may include any quantity of signal paths. In some cases, the clock signal CK (e.g., a CK_t signal and a CK_c signal) may provide a timing reference for command and addressing operations for the memory device 110, or other system-wide operations for the memory device 110. The clock signal CK therefore may be variously referred to as a control clock signal CK, a command clock signal CK, or a system clock signal CK. The system clock signal CK may be generated by a system clock, which may include one or more hardware components (e.g., oscillators, crystals, logic gates, transistors, or the like).

In some cases, the channels 115 may include one or more data (DQ) channels 190. The data channels 190 may be configured to communicate data and/or control information between the external memory controller 105 and the memory device 110. For example, the data channels 190 may communicate information (e.g., bi-directional) to be written to the memory device 110 or information read from the memory device 110. The data channels 190 may communicate signals that may be modulated using a variety of different modulation schemes (e.g., NRZ, PAM4).

In some cases, the channels 115 may include one or more other channels 192 that may be dedicated to other purposes. These other channels 192 may include any quantity of signal paths.

In some cases, the other channels 192 may include one or more write clock signal (WCK) channels. While the ‘W’ in WCK may nominally stand for “write,” a write clock signal WCK (e.g., a WCK_t signal and a WCK_c signal) may provide a timing reference for access operations generally for the memory device 110 (e.g., a timing reference for both read and write operations). Accordingly, the write clock signal WCK may also be referred to as a data clock signal WCK. The WCK channels may be configured to communicate a common data clock signal between the external memory controller 105 and the memory device 110. The data clock signal may be configured to coordinate an access operation (e.g., a write operation or read operation) of the external memory controller 105 and the memory device 110. In some cases, the write clock signal may be a differential output (e.g., a WCK_t signal and a WCK_c signal) and the signal paths of the WCK channels may be configured accordingly. A WCK channel may include any quantity of signal paths. The data clock signal WCK may be generated by a data clock, which may include one or more hardware components (e.g., oscillators, crystals, logic gates, transistors, or the like).

The channels 115 may couple the external memory controller 105 with the memory device 110 using a variety of different architectures. Examples of the various architectures may include a bus, a point-to-point connection, a crossbar, a high-density interposer such as a silicon interposer, or channels formed in an organic substrate or some combination thereof. For example, in some cases, the signal paths may at least partially include a high-density interposer, such as a silicon interposer or a glass interposer.

Signals communicated over the channels 115 may be modulated using a variety of different modulation schemes. In some cases, a binary-symbol (or binary-level) modulation scheme may be used to modulate signals communicated between the external memory controller 105 and the memory device 110. A binary-symbol modulation scheme may be an example of a M-ary modulation scheme where M is equal to two. Each symbol of a binary-symbol modulation scheme may be configured to represent one bit of digital data (e.g., a symbol may represent a logic 1 or a logic 0). Examples of binary-symbol modulation schemes include, but are not limited to, non-return-to-zero (NRZ), unipolar encoding, bipolar encoding, Manchester encoding, pulse amplitude modulation (PAM) having two symbols (e.g., PAM2), and/or others.

In some cases, a multi-symbol (or multi-level) modulation scheme may be used to modulate signals communicated between the external memory controller 105 and the memory device 110. A multi-symbol modulation scheme may be an example of a M-ary modulation scheme where M is greater than or equal to three. Each symbol of a multi-symbol modulation scheme may be configured to represent more than one bit of digital data (e.g., a symbol may represent a logic 00, a logic 01, a logic 10, or a logic 11). Examples of multi-symbol modulation schemes include, but are not limited to, PAM4, PAM8, etc., quadrature amplitude modulation (QAM), quadrature phase shift keying (QPSK), and/or others. A multi-symbol signal or a PAM4 signal may be a signal that is modulated using a modulation scheme that includes at least three levels to encode more than one bit of information. Multi-symbol modulation schemes and symbols may alternatively be referred to as non-binary, multi-bit, or higher-order modulation schemes and symbols.

System 100 may be configured to employ techniques for improved refresh rate management for memory devices 110. The memory device 110 may receive refresh commands for refreshing a memory array 170 from a host device (e.g., from external memory controller 105). Memory device 110 may determine a refresh rate (e.g., quantity of commands received within a defined time window) associated with the received refresh commands to determine whether the refresh rate satisfies (e.g., equals or is above) a threshold. The threshold may specify a desired or target refresh rate for memory array 170 based on a condition (e.g., temperature) of memory device 110. For example, the threshold may define a time window for receiving a defined quantity of refresh commands, which may change as the temperature of memory device changes—e.g., the time window may decrease as the temperature of memory device 110 increases.

In the event that the refresh rate associated with refresh commands is determined to be below the threshold, memory device 110 may take action. In one example, memory device 110 may transmit signaling to a host (e.g., external memory controller 105) that informs host device that the refresh rate is below the threshold. Additionally or alternatively, memory device 110 may switch from a first mode of operation to a second mode of operation (e.g., safe mode) in response to determining that the refresh rate is below the threshold. In the safe mode, memory device 110 may take actions to refresh memory array 170 at a rate that maintains data integrity within array 170 (e.g., maintains stored logic states in memory cells). In some cases, memory device may remain in a safe mode until it receives an acknowledgement from a host device, at which point the memory device may switch back to a first mode of operation.

FIG. 2 illustrates an example of a memory die 200 as disclosed herein. The memory die 200 may be an example of the memory dice 160 described with reference to FIG. 1. In some cases, the memory die 200 may be referred to as a memory chip, a memory device, or an electronic memory apparatus. The memory die 200 may include one or more memory cells 205 that are programmable to store different logic states. Each memory cell 205 may be programmable to store two or more states. For example, the memory cell 205 may be configured to store one bit of digital logic at a time (e.g., a logic 0 and a logic 1). In some cases, a single memory cell 205 (e.g., a multi-level memory cell) may be configured to store more than one bit of digit logic at a time (e.g., a logic 00, logic 01, logic 10, or a logic 11).

A memory cell 205 may store a charge representative of the programmable states in a capacitor. DRAM architectures may include a capacitor that includes a dielectric material to store a charge representative of the programmable state. In other memory architectures, other storage devices and components are possible. For example, nonlinear dielectric materials may be employed.

Operations such as reading and writing may be performed on memory cells 205 by activating or selecting access lines such as a word line 210 and/or a digit line 215. In some cases, digit lines 215 may also be referred to as bit lines. References to access lines, word lines and digit lines, or their analogues, are interchangeable without loss of understanding or operation. Activating or selecting a word line 210 or a digit line 215 may include applying a voltage to the respective line.

The memory die 200 may include the access lines (e.g., the word lines 210 and the digit lines 215) arranged in a grid-like pattern. Memory cells 205 may be positioned at intersections of the word lines 210 and the digit lines 215. By biasing a word line 210 and a digit line 215 (e.g., applying a voltage to the word line 210 or the digit line 215), a single memory cell 205 may be accessed at their intersection.

Accessing the memory cells 205 may be controlled through a row decoder 220 or a column decoder 225. For example, a row decoder 220 may receive a row address from the local memory controller 260 and activate a word line 210 based on the received row address. A column decoder 225 may receive a column address from the local memory controller 260 and may activate a digit line 215 based on the received column address. For example, the memory die 200 may include multiple word lines 210, labeled WL_1 through WL_M, and multiple digit lines 215, labeled DL_1 through DL_N, where M and N depend on the size of the memory array. Thus, by activating a word line 210 and a digit line 215, e.g., WL_1 and DL_3, the memory cell 205 at their intersection may be accessed. The intersection of a word line 210 and a digit line 215, in either a two-dimensional or three-dimensional configuration, may be referred to as an address of a memory cell 205.

The memory cell 205 may include a logic storage component, such as capacitor 230 and a switching component 235. The capacitor 230 may be an example of a dielectric capacitor or a ferroelectric capacitor. A first node of the capacitor 230 may be coupled with the switching component 235 and a second node of the capacitor 230 may be coupled with a voltage source 240. In some cases, the voltage source 240 may be the cell plate reference voltage, such as Vpl, or may be ground, such as Vss. In some cases, the voltage source 240 may be an example of a plate line coupled with a plate line driver. The switching component 235 may be an example of a transistor or any other type of switch device that selectively establishes or de-establishes electronic communication between two components.

Selecting or deselecting the memory cell 205 may be accomplished by activating or deactivating the switching component 235. The capacitor 230 may be in electronic communication with the digit line 215 using the switching component 235. For example, the capacitor 230 may be isolated from digit line 215 when the switching component 235 is deactivated, and the capacitor 230 may be coupled with digit line 215 when the switching component 235 is activated. In some cases, the switching component 235 is a transistor and its operation may be controlled by applying a voltage to the transistor gate, where the voltage differential between the transistor gate and transistor source may be greater or less than a threshold voltage of the transistor. In some cases, the switching component 235 may be a p-type transistor or an n-type transistor. The word line 210 may be in electronic communication with the gate of the switching component 235 and may activate/deactivate the switching component 235 based on a voltage being applied to word line 210.

A word line 210 may be a conductive line in electronic communication with a memory cell 205 that is used to perform access operations on the memory cell 205. In some architectures, the word line 210 may be in electronic communication with a gate of a switching component 235 of a memory cell 205 and may be configured to control the switching component 235 of the memory cell. In some architectures, the word line 210 may be in electronic communication with a node of the capacitor of the memory cell 205 and the memory cell 205 may not include a switching component.

A digit line 215 may be a conductive line that connects the memory cell 205 with a sense component 245. In some architectures, the memory cell 205 may be selectively coupled with the digit line 215 during portions of an access operation. For example, the word line 210 and the switching component 235 of the memory cell 205 may be configured to couple and/or isolate the capacitor 230 of the memory cell 205 and the digit line 215. In some architectures, the memory cell 205 may be in electronic communication (e.g., constant) with the digit line 215.

The sense component 245 may be configured to detect a state (e.g., a charge) stored on the capacitor 230 of the memory cell 205 and determine a logic state of the memory cell 205 based on the stored state. The charge stored by a memory cell 205 may be extremely small, in some cases. As such, the sense component 245 may include one or more sense amplifiers to amplify the signal output by the memory cell 205. The sense amplifiers may detect small changes in the charge of a digit line 215 during a read operation and may produce signals corresponding to a logic state 0 or a logic state 1 based on the detected charge. During a read operation, the capacitor 230 of memory cell 205 may output a signal (e.g., discharge a charge) to its corresponding digit line 215. The signal may cause a voltage of the digit line 215 to change. The sense component 245 may be configured to compare the signal received from the memory cell 205 across the digit line 215 to a reference signal 250 (e.g., reference voltage). The sense component 245 may determine the stored state of the memory cell 205 based on the comparison.

For example, in binary-signaling, if digit line 215 has a higher voltage than the reference signal 250, the sense component 245 may determine that the stored state of memory cell 205 is a logic 1 and, if the digit line 215 has a lower voltage than the reference signal 250, the sense component 245 may determine that the stored state of the memory cell 205 is a logic 0. The sense component 245 may include various transistors or amplifiers to detect and amplify a difference in the signals. The detected logic state of memory cell 205 may be output through column decoder 225 as output 255. In some cases, the sense component 245 may be part of another component (e.g., a column decoder 225, row decoder 220). In some cases, the sense component 245 may be in electronic communication with the row decoder 220 or the column decoder 225.

The local memory controller 260 may control the operation of memory cells 205 through the various components (e.g., row decoder 220, column decoder 225, and sense component 245). The local memory controller 260 may be an example of the local memory controller 165 described with reference to FIG. 1. In some cases, one or more of the row decoder 220, column decoder 225, and sense component 245 may be co-located with the local memory controller 260. The local memory controller 260 may be configured to receive commands and/or data from an external memory controller 105 (or a device memory controller 155 described with reference to FIG. 1), translate the commands and/or data into information that can be used by the memory die 200, perform one or more operations on the memory die 200, and communicate data from the memory die 200 to the external memory controller 105 (or the device memory controller 155) in response to performing the one or more operations.

The local memory controller 260 may generate row and column address signals to activate the target word line 210 and the target digit line 215. The local memory controller 260 may also generate and control various voltages or currents used during the operation of the memory die 200. In general, the amplitude, shape, or duration of an applied voltage or current discussed herein may be adjusted or varied and may be different for the various operations discussed in operating the memory die 200.

In some cases, the local memory controller 260 may be configured to perform a write operation (e.g., a programming operation) on one or more memory cells 205 of the memory die 200. During a write operation, a memory cell 205 of the memory die 200 may be programmed to store a desired logic state.

In some cases, a plurality of memory cells 205 may be programmed during a single write operation. The local memory controller 260 may identify a target memory cell 205 on which to perform the write operation. The local memory controller 260 may identify a target word line 210 and a target digit line 215 in electronic communication with the target memory cell 205 (e.g., the address of the target memory cell 205). The local memory controller 260 may activate the target word line 210 and the target digit line 215 (e.g., applying a voltage to the word line 210 or digit line 215), to access the target memory cell 205. The local memory controller 260 may apply a specific signal (e.g., voltage) to the digit line 215 during the write operation to store a specific state (e.g., charge) in the capacitor 230 of the memory cell 205, the specific state (e.g., charge) may be indicative of a desired logic state.

In some cases, the local memory controller 260 may be configured to perform a read operation (e.g., a sense operation) on one or more memory cells 205 of the memory die 200. During a read operation, the logic state stored in a memory cell 205 of the memory die 200 may be determined. In some cases, a plurality of memory cells 205 may be sensed during a single read operation. The local memory controller 260 may identify a target memory cell 205 on which to perform the read operation. The local memory controller 260 may identify a target word line 210 and a target digit line 215 in electronic communication with the target memory cell 205 (e.g., the address of the target memory cell 205). The local memory controller 260 may activate the target word line 210 and the target digit line 215 (e.g., applying a voltage to the word line 210 or digit line 215), to access the target memory cell 205.

The target memory cell 205 may transfer a signal to the sense component 245 in response to biasing the access lines. The sense component 245 may amplify the signal. The local memory controller 260 may fire the sense component 245 (e.g., latch the sense component) and thereby compare the signal received from the memory cell 205 to the reference signal 250. Based on that comparison, the sense component 245 may determine a logic state that is stored on the memory cell 205. The local memory controller 260 may communicate the logic state stored on the memory cell 205 to the external memory controller 105 (or the device memory controller 155) as part of the read operation.

In some memory architectures, accessing the memory cell 205 may degrade or destroy the logic state stored in a memory cell 205. For example, a read operation performed in DRAM architectures may partially or completely discharge the capacitor of the target memory cell. The local memory controller 260 may perform a rewrite operation or a refresh operation to return the memory cell to its original logic state. The local memory controller 260 may rewrite the logic state to the target memory cell after a read operation. In some cases, the rewrite operation may be considered part of the read operation. Additionally, activating a single access line, such as a word line 210, may disturb the state stored in some memory cells in electronic communication with that access line. Thus, a rewrite operation or refresh operation may be performed on one or more memory cells that may not have been accessed.

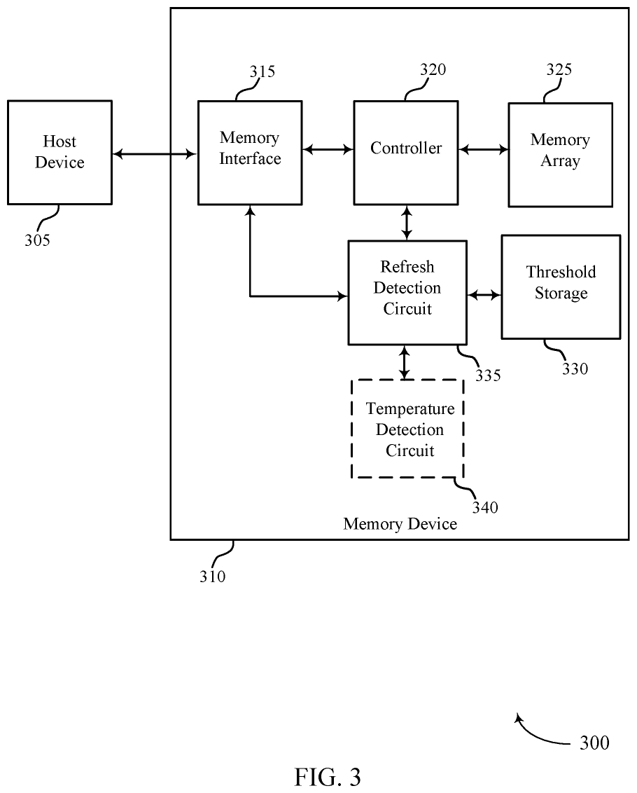

FIG. 3 illustrates an example of a system 300 that supports techniques for improved refresh management for a memory device. The system 300 may include one or more components described herein with reference to FIGS. 1 and 2, among others. For example, the system 300 may include a host device 305, which may be an example of the external memory controller 105 as described with reference to FIG. 1; a memory device 310, which may be an example of the memory device 110, the memory dice 160, or the memory die 200 as described with reference to FIGS. 1 and 2; a controller 320, which may be an example of the device memory controller 155, one or more local memory controllers 165, or the local memory controller 260 as described with reference to FIGS. 1 and 2, or any combination thereof; a memory array 325, which may be an example of the memory arrays 170 as described with reference to FIG. 1. The memory device 310 may also include threshold storage 330, a refresh detection circuit 335, and a temperature detection circuit 340.

Host device 305 may send commands to memory device 310, which may be received via memory interface 315. The commands may include refresh commands to perform one or more refresh cycles (e.g., refresh memory cells at one or more physical rows of memory array 325). Controller 320 may receive commands from the memory interface 315, process the commands, and execute the commands on memory array 325. Controller 320 may operate the memory array 325 according to various modes of operation.

Memory array 325 may include one or more memory banks, each of which may comprise one or more rows and/or one or more columns. For example, upon receiving a refresh command to perform one or more refresh cycles, controller 320 may initiate refresh of memory cells at one or more physical locations (e.g., rows, columns, etc.). The refresh command may specify an address for refresh (e.g., a row address), and memory device 310 (e.g., controller 320) may determine one or more additional addresses for refresh according to an internal counter (e.g., by incrementing the row address specified by the refresh command so as to obtain one or more additional row addresses). In this regard, one or more refresh cycles may be initiated by controller 320 receiving refresh commands from host device 305, and refresh of corresponding (e.g., specified or otherwise determined) memory cells with memory array 325 may be carried out internally by controller 320.

In some cases, host device 305 may initiate a burst refresh within memory device 310, where a series of refresh cycles are consecutively performed by memory device 310 until all rows of memory array 325 have been refreshed. Burst refresh may be initiated at multiple physical locations (e.g., multiple rows) in parallel (e.g., at similar times), offset according to some pattern (e.g., different rows at different times), or the like. In some cases, host device 305 may initiate distributed refresh within memory device 310, where refresh cycles are interspersed with other accesses of memory array 325 (e.g., read, write, etc.). In other cases, host device 305 may send a command for memory device 310 to perform a refresh. In this case, controller 320 may direct refresh, such as a burst refresh, a distributed refresh, or the like.

Threshold storage 330 may store at least one refresh threshold (e.g., defined time window for receiving a given quantity of refresh commands) for refreshing memory array 325. A refresh threshold may define a refresh parameter for one or more memory banks in memory array 325. For example, the refresh threshold (e.g., refresh parameter) may define a time window for receiving a given quantity of commands from host device 305. The time window may be set (e.g., configured or determined) to maintain data integrity (e.g., preserve a stored charge) within memory cells of memory array 325 in compliance with a reliability constraint. In some cases, host device 305 may coordinate sending refresh commands with sending other access commands such as read or write commands for reading or writing to memory cells within memory array 325.

In some cases, threshold storage 330 may store multiple refresh thresholds that specify different refresh parameters (e.g., different time windows for receiving a given quantity of refresh commands), each corresponding to different conditions of memory device 310. In one case, threshold storage 330 may store a first refresh threshold associated with a first temperature range and a second refresh threshold associated with a second temperature range. That is, threshold storage 330 may store a first refresh threshold (e.g., first time window for receiving a given amount of refresh commands) that is implemented at memory array 325 when a temperature associated with memory array 325 (e.g., case temperature) is below a transition temperature (e.g., a temperature at the upper bound of the first temperature range and the lower bound of the second temperature range).

Further, threshold storage 330 may store a second refresh threshold (e.g., second time window for receiving the given amount of refresh commands) that is implemented at memory array 325 when the temperature associated with memory array 325 is at or above the transition temperature. In some cases, the first refresh threshold may correspond to (e.g., specify) a greater time window (e.g., slower refresh parameter) than the second refresh threshold.

In some cases, threshold storage 330 may store a set of refresh thresholds associated with varying conditions of memory array 325. For example, threshold storage 330 may store multiple different refresh thresholds each relating to different temperature conditions (e.g., temperature ranges) associated with memory array 325. In this regard, threshold storage 330 may define a variety of relationships between a condition (e.g., temperature) associated with memory array 325 and a corresponding refresh threshold. In a first example, a set of refresh thresholds stored in threshold storage 330 may define a linear relationship between a refresh parameter and a temperature associated with memory array 325.

Accordingly, an increase in temperature at memory array 325 may result in a linear decrease of the refresh threshold (e.g., a 2× increase in the temperature of memory array results in a 2× decrease in the time window for receiving a given quantity of refresh commands). In a second example, a set of refresh thresholds stored in threshold storage 330 may define a non-linear relationship between a refresh parameter and a temperature associated with memory array 325. In this example, an increase in temperature at memory array 325 may result in, for example, an exponential decrease of the refresh parameter (e.g., a 2× increase in the temperature of memory array results in a 4× decrease in the time window for receiving the given quantity of refresh commands). Threshold storage 330 may store one or more sets of refresh thresholds that are determined according to operating parameters of memory device 310.

For example, memory array 325 may be associated with a transition temperature at which it is desirable to have the refresh rate double once the memory array reaches that temperature. In this case, threshold storage may store a more granular set of refresh thresholds (e.g., a greater quantity of refresh thresholds each correlating to smaller changes in temperature) around the transition temperature to help facilitate desired operation of memory array 325.

Threshold storage 330 may store refresh threshold information that may be selected based on various dynamic conditions of memory device 310. Conditions of memory device 310 that dynamically change may include temperature as described herein, as well as other measured, programmed or determined conditions. For example, a refresh threshold based on other conditions such as external magnetic fields, radiation exposure, outputs from error correcting code (ECC) operations (e.g., a count of error flags), read/write frequency at memory array 325, host device 305 commands, a quantity of read/write commands, lifecycle data, critical read/write operations, sensor outputs (e.g., accelerometers, gyroscopic sensors, inferred sensors, etc.), or the like, or a combination thereof. Accordingly, refresh threshold stored by threshold storage 330 may be configured or programmed to relate a variety of conditions to one or more sets of refresh thresholds.

Threshold storage 330 may store one or more configured sets of refresh thresholds that is set by a vendor such as a memory device manufacturer. In this regard, threshold storage 330 may include, for example, a value for the configured refresh thresholds that is hard-wired (e.g., stored in one or more fuses, anti-fuses, or the like) or otherwise stored in one or more memory elements that are non-volatile and can be preconfigured (e.g., Read-Only Memory (ROM) or One-Time-Programable (OTP) memory). In some cases, a configured refresh threshold may have a value based on one or more characteristics of memory array 325. For example, the refresh threshold may be determined based on transistor leakage currents or other leakage mechanisms for memory cells within memory array 325. In some cases, this may include determining one or more sets of refresh thresholds based on worst-case memory cells (e.g., memory cells that lose a stored charge the fastest). This may be implementation specific. For example, for critical or low failure applications (e.g., autonomous vehicles) sets of refresh thresholds may be configured to ensure that substantially all memory cells in memory array 325 are refreshed before losing a logic state.

In some cases, the configured refresh threshold(s) stored by threshold storage 330 may be adjustable or overwritable (e.g., as a trim parameter). For example, threshold storage 330 may include OTP memory (e.g., fuses or anti-fuses) for storing the configured refresh threshold(s), and host device 305 may program the configured refresh threshold(s) as part of a trim process or upon initial memory device 310 power-up or configuration (e.g., the first time host device 305 accesses memory device 310). After programing, the configured refresh threshold(s) may then be fixed for subsequent power cycles.

According to various aspects, threshold storage 330 may include a capability of storing one or more sets of programmed (e.g., not preconfigured, programmed dynamically during operation of memory device 310) refresh thresholds. The programmed refresh threshold(s) may be based on an application of memory device 310. In some cases, host device 305 may program threshold storage 330 (by transmitting related signaling to controller 320 via memory interface 315) to store a programmed refresh threshold. In some cases, host device 305 may program threshold storage 330 to store a programmable refresh threshold by programing one or more mode registers within memory device 310 (e.g., threshold storage 330 may include one or more mode registers). In some cases, threshold storage 330 may include non-volatile memory (e.g., One-Time-Programable (OTP) memory, Electronically Erasable Programable Read-Only Memory (EEPROM), Ferroelectric Random Access Memory (FRAM), Magnetoresistive Random Access Memory (RAM)) for storing one or more sets of programmed refresh thresholds. Alternatively, threshold storage 330 may include volatile memory (e.g., DRAM, Static Random Access Memory (SRAM), registers) for storing the set(s) of programmed refresh thresholds. Host device 305, may program threshold storage 330 to store programmed refresh thresholds, for example, upon initialization (e.g., boot or reboot of memory device 310) or configuration.

Refresh detection circuit 335 may interface with threshold storage 330 and temperature detection circuit 340 to determine if a refresh rate associated with refresh commands received from host device 305 satisfies a refresh threshold. In some cases, refresh detection circuit 335 may receive (access or retrieve) one or more refresh thresholds from threshold storage 330. A refresh threshold received/accessed by refresh detection circuit 335 and in use by refresh detection circuit 335 to evaluate the refresh rate may be referred to as an operative threshold. In this regard, refresh detection circuit 335 may determine a time window (e.g., duration) for monitoring refresh commands based on the operative threshold.

In some cases, refresh detection circuit 335 may receive an indication of when (e.g., based on a time, clock cycle, internal counter, or the like) refresh commands are received from host device 305. In some cases, refresh detection circuit 335 may count the quantity of refresh commands received from host device 305 over the time window associated with the operative threshold and compare the counted quantity of refresh commands to a minimum quantity of refresh commands associated with (e.g., indicated in or otherwise specified for) the operative threshold.

If the quantity of refresh commands within the time window is less than the minimum quantity of commands, then the refresh detection circuit 335 may determine that the refresh rate associated with the refresh commands received from host device 305 is below the threshold. Alternatively or additionally, refresh detection circuit 335 may count a set quantity of refresh commands received from host device 305 and determine a time interval it took to receive the set quantity of refresh commands. In this regard, refresh detection circuit 335 may compare the time it took to receive the set quantity of commands from host device 305, with a maximum time duration associated with the operative threshold. Thus, the operative threshold may in some cases indicate a target time for receiving a given quantity of refresh commands. If the time it took to receive the given quantity of refresh commands is greater than the time associated with the operative threshold, then the refresh detection circuit 335 may determine that the refresh rate associated with the refresh commands received from host device 305 is below the threshold.

Refresh detection circuit 335 may be configured to determine one or more refresh thresholds stored at threshold storage 330 to use as an operative threshold based on a condition (e.g., temperature, host device commands, sensor outputs, etc.) of memory array 325, memory device 310, temperature detection circuit 340, or the like, or a combination thereof. In a first example, refresh detection circuit 335 may receive a temperature indication associated with memory array 325 (e.g., case temperature) from temperature detection circuit 340. Based on the temperature indication, refresh detection circuit may determine an appropriate refresh threshold and accesses/receive that threshold from threshold storage 330. Refresh detection circuit 335 may monitor refresh commands received at memory interface 315 (e.g., based on signaling from memory interface 315 or controller 320) and determine whether the refresh commands received from host device 305 satisfies the threshold (e.g., controller 320 receives equal to or greater than the given quantity of commands for the time period defined in the operative threshold).

Refresh detection circuit 335 may include circuit components configured to determine if the refresh commands received from host device 305 satisfy the refresh threshold (e.g., operative threshold). The refresh detection circuit 335 may be or include a counter, a timer, internal oscillator, or the like. The refresh threshold may indicate a set or target refresh rate (e.g., a defined quantity of refresh commands that must be received within a defined time window to satisfy the refresh threshold).

Refresh detection circuit 335 may receive an indication of the refresh commands (e.g., refresh commands received from host device 305) from memory interface 315, or controller 320. For example, controller 320 may provide an indication of the refresh command to refresh detection circuit 335. Based on the refresh commands or indications thereof, refresh detection circuit 335 may determine an associated refresh rate and compare the refresh rate with the operative threshold. If refresh detection circuit 335 determines that the refresh rate is below the threshold, refresh detection circuit 335 may provide an indication to controller 320. The indication may include information indicating that refresh commands are below the threshold. If refresh detection circuit 335 determines that the refresh rates is equal to or above the threshold (e.g., satisfies the threshold), refresh detection circuit 335 may continue to monitor incoming refresh commands, and may in some cases update/adjust the operative refresh threshold based on one or more evolving conditions (e.g., the temperature) of the memory device 310, and determine whether refresh commands received from host device 305 satisfy the updated operative threshold.

Temperature detection circuit 340 may monitor a current temperature associated with memory array 325 (e.g., case temperature). Temperature detection circuit 340 may be integrated with memory device 310 (e.g., may be an on-die temperature sensor), may be independent of memory device 310, or a combination thereof. For example, temperature detection circuit 340 may receive measured temperature data from an internal or external monitor (e.g., thermocouple, resistance temperature detector (RTD) thermistor, or the like) via memory interface 315, an interface associated with temperature detection circuit 340, a pin of memory device, or the like.

FIG. 4 shows an example diagram of a process flow 400 that supports techniques for improved refresh management for a memory device. The features of process flow 400 may be implemented or performed by a memory device (e.g., the memory device 110, the memory dice 160, the memory die 200, or the memory device 310 described with reference to FIGS. 1 through 3, among others) or a component of a memory device such as the device memory controller 155, the local memory controllers 165, the local memory controller 260, the controller 320, or the refresh detection circuit 335 as described with reference to FIGS. 1 through 3.

At block 405, a memory device may receive a set of commands from a host device (e.g., via a memory interface 315). The set of commands may include refresh commands, activate commands, read commands, write commands, or the like. The memory device may be operating according to a first mode, which may support access to a memory array (e.g., a memory array 325) at the memory device. In some cases, the first mode may be referred to as a mission mode or access mode, and the commands included in the set of commands may be referred to as mission mode or access commands.

For example, while the memory device is in the first mode of operation, a host device (e.g., host device 305) may send a plurality of refresh commands to memory device (e.g., memory device 310) for refreshing a memory array (e.g., memory array 325). The host device may send the refresh commands at specific intervals in order to maintain logic states stored in the memory array according to reliability criteria. Host device may determine the rate (e.g., intervals) at which to send refresh commands based on a variety of criteria. In some cases, host device may send refresh commands according to configured or programmed refresh rates stored at host device. In other cases, a host device may determine a refresh rate based on communications from memory device or indications from other peripherals. In some cases, a host device may schedule refresh commands based on (e.g., around) other commands, such as read commands, write commands, or the like. That is, a host device may need to schedule or modify the timing of refresh commands based on sending read or write commands to the memory device.

At block 410, the memory device may determine whether a threshold associated with refresh commands for the memory array has been met. For example, refresh detection circuit 335 may determine an operative threshold for evaluating a refresh rate associated with refresh commands received from host device 305. In some cases, the operative threshold is determined based on a condition of memory device 310 or memory array 325. For example, as described herein, refresh detection circuit 335 may receive a temperature indication associated with memory array 325 from temperature detection circuit 340. Using the temperature indication, refresh detection circuit 335 may identify a threshold stored at threshold storage 330 for evaluating the refresh commands. The identified threshold may be referred to as an operative threshold, which may define a time window for receiving a given quantity of refresh commands.

Memory interface 315 or controller 320 may send refresh detection circuit 335 an indication of refresh commands received from host device 305. Refresh detection circuit 335 may determine a whether a refresh rate associated with the received commands satisfies the operative threshold (e.g., whether a quantity of refresh commands received within the determined time window is equal to or greater than the specified quantity of refresh commands, and/or whether a time needed to receive a certain quantity of refresh commands is less than or equal to a specified time window).

In some cases, this may include refresh detection circuit counting the quantity of refresh indications received, over the time window specified in the operative threshold, and comparing the counted refresh commands to the quantity of commands defined in the operative threshold. In some cases, this may include refresh detection circuit counting the quantity of refresh indications received until the count reaches a certain quantity, and comparing the time to receive the certain quantity of refresh commands to a time duration defined in the operative threshold. A quantity of received refresh commands and a time duration over which the quantity of refresh commands is received may be determined according to an internal (e.g., on die) timer such as an oscillator, counter, or the like.

In a first case, the memory device may determine at block 410 that the operative threshold is satisfied and remain in a first operation mode (e.g., a mission mode or access mode) and receive additional host-issued commands (e.g., refresh command, read commands, write commands, or the like) at block 405.

In a second case, the memory device may determine at block 410 that the operative threshold is not satisfied and proceed to block 415.

In some cases, the memory device (e.g., refresh detection circuit 335) may be configured to determine the operative threshold based on one or more conditions (e.g., the temperature) of the memory device. This may be application specific. For example, the memory device may be associated with an autonomous vehicle, and thus be subjected to random and extreme temperature changes.

Additionally, in some cases it may be desirable to change the frequency of determining or applying a new operative threshold, for example based on a rate of temperature change. For example, in a case where a memory array is heating up, circuitry (e.g., controller 320, refresh detection circuit 335, temperature detection circuit 340, or a combination thereof) may increase the frequency at which refresh detection circuit 335 receives a temperature indication, selects an operative threshold and determines whether refresh commands satisfy the operative threshold. Additionally or alternatively, refresh detection circuit 335 may choose an operative threshold based on a predicted temperature for memory array. That is, if memory array is heating up rapidly, refresh detection circuit 335 or temperature detection circuit 340 may predict a future temperature of memory array, for example, based on extrapolation of measured temperature points. Accordingly, refresh detection circuit 335 may select an operative threshold from threshold storage 330 based on that future predicted temperature.

At block 410, the memory device may determine additional metrics associated with received refresh commands. For example, refresh detection circuit 335 may determine a deviation from an operative threshold. The deviation from the operative threshold could represent a buffer range, error range, or other range representing tolerated refresh rates that are below the operative threshold, or the like. In this regard, refresh detection circuit 335 may determine whether a refresh rate associated with refresh commands is within a tolerated deviation from the operative threshold. One implementation of this may occur if refresh detection circuit 335 determines that a refresh rate is below an operative threshold, but within (e.g., above) the deviation of the operative threshold. Accordingly, refresh detection circuit 335 may transmit signaling to controller 320 indicating that the refresh commands satisfy the operative threshold, but are at risk of falling below the threshold.

Additionally or alternatively, in some cases determining whether the refresh rate for the received refresh commands falls below the operative threshold may include determining a duration for which the refresh rate is below the operative threshold. For example, the memory device may determine a quantity of clock cycles or refresh cycles for which a refresh rate is below an operative threshold. In this regard, the circuitry (e.g., refresh detection circuit 335, controller 320 or threshold storage 330) may determine that a refresh rate is below a threshold based on a duration (e.g., multiple clock cycles, multiple refresh cycles, etc.) that the refresh rate is below the operative threshold, and/or the extent (deviation) to which the refresh rate is below the operative threshold. This may include monitoring multiple clock cycle durations, refresh cycles, or the like to track how often a refresh rate is below the operative threshold over multiple cycles (e.g., refresh rate is below the threshold for 4 out of 10 cycles). Accordingly, at block 410, circuitry may determine that a refresh rate is below an operative threshold based on multiple refresh cycles.

At block 415, based on determining at 410 that the refresh rate associated with the refresh commands received at 405 does not satisfy (e.g., is below) the operative threshold, the memory device may transmit signaling to the host device alerting host device that the refresh rate is below the threshold (e.g., operative threshold). In some cases, the memory device may include a controller (e.g., controller 320), which may alert the host device by sending a flag (e.g., a value that acts as a signal) or some other indication to the host device. Additionally or alternatively, a controller of the memory device may send a threshold (e.g., the operative threshold) to the host device. In this regard, a host device may use the operative threshold to modify the rate at which the host device sends refresh commands to the memory device. In some cases, a pin of the memory device may be used to signal the flag or threshold to a host device. For example, by driving a signal at the pin either high or low to indicate that the operative threshold is not satisfied. In some cases, more than one channel 115 may be used to signal the flag or threshold to a host device.

In some cases, the memory device may send to the host device data associated with the refresh rate evaluated at 410 or otherwise associated with the received commands, a temperature associated with memory array, one or more refresh thresholds, or a combination thereof. For example, at block 415 the memory device may send host device a time window in which at least a specified quantity of refresh commands must be received by the memory device. In other cases, the memory device may send host device a current temperature indication for memory array as a flag, and host may use the temperature indication to determine an operative threshold whether refresh commands sent by the host device are satisfying the operative threshold.

In some cases, the host device may transmit signaling to the memory device to notify the memory device that it has received the indication that the refresh rate is below an operative threshold. For example, the host device may send a flag or other acknowledgement (e.g., command sequence or other signaling) to memory device. In some cases, the host device may send the signaling via a pin of the host device, through one or more commands (e.g., mode registry or access commands), through one or more channels (e.g., channels 115), or a combination thereof. Additionally or alternatively, the host device may transmit signaling to the memory device by sending a new set of refresh commands with a refresh rate that satisfies the operative threshold. In some cases, the host device may transmit signaling to the memory device by sending one or more commands to the memory device (e.g., activate, read, or write commands).

In some cases, the memory device may alert the host device at block 415, without taking other actions (e.g., without switching an operating mode as otherwise described herein) to allow the host device to determine a course of action. In some cases, the host device may be in the middle of mission-critical activities (e.g., for autonomous driving), and may need to access the memory device to execute read or write commands before issuing more refresh commands or refresh commands at an increased rate. In this regard, the memory device may be configured to alert the host device that an operative threshold is not satisfied. In some cases, the memory device may wait a duration (e.g., quantity of refresh cycles, clock cycles, etc.) before taking a course of action as otherwise described herein. For example, the memory device may wait to determine whether the host device responds by sending signaling to memory device as discussed herein. This may include the memory device waiting a specified duration to receive a new set of refresh commands from the host device or commands indicating that the host device is performing mission-critical commands.

FIG. 5 shows an example diagram of a process flow 500 that supports techniques for improved refresh management for a memory device. The features of process flow 500 may be implemented or performed by a memory device (e.g., the memory device 110, the memory dice 160, the memory die 200, or the memory device 310 described with reference to FIGS. 1 through 3, among others) or a component of a memory device such as the device memory controller 155, the local memory controllers 165, the local memory controller 260, the controller 320, or the refresh detection circuit 335 as described with reference to FIGS. 1 through 3.

Blocks 505, 510, and 515 may correspond to blocks 405, 410, and 415, respectively, as described with reference to FIG. 4. Accordingly, blocks 505, 510, and 515 may perform similar functions and include similar features as described in reference to the corresponding blocks in FIG. 4. Additionally or alternatively, at block 515, the memory device may be further configured to proceed to block 520 in association with transmitting an alert to the host device.

At block 520, the memory device may transition from the first mode of operation to a second mode of operation (e.g., safe mode) in response to determining that the operative threshold is not satisfied. In the second mode of operation, the memory device may initiate one or more processes to refresh the memory array within the parameters indicated in the operative threshold. The second mode may include the memory device taking over or modifying commands (e.g., refresh commands) that were carried out by the host device in the first mode of operation. In some cases, the memory device may determine to transition to one safe mode of operation from a plurality of different safe mode of operations. A safe mode of operation may include implementing refresh operations that meet the operative threshold indicated for the memory array.

For example, the memory device may enter a self-refresh mode as part of a safe mode, where the memory device manages refresh operations. Such a mode may include a controller refreshing memory cells using an internal oscillator, internal counters, or the like, or a combination thereof. Additionally or alternatively, the memory device may, as part of a safe mode, block commands (e.g., mission mode or access commands) to one or more parts of memory array. For example, the memory device may lock out or ignore mission mode or accesses mode commands received from the host device.

As another example, the memory device may, as part of a safe mode, alter a refresh process for memory array based on receiving refresh commands from a host device. For example, in response to entering the safe mode, memory device may alter the response of the controller to receiving a refresh commands from the host device.

In some cases, the controller may increase the rate at which refresh occurs within the memory array. For example, the memory device may adjust the quantity of memory cells refreshed in response to a single refresh command (e.g., may adjust a row multiplier) in addition to alerting the host. This may be referred to as a catch-up mode, in which the controller initiates a greater quantity of refresh cycles at the memory array in response to refresh commands from the host device, and may be or may be included in a safe mode.

Additionally or alternatively, a catch-up mode may include the controller adjusting the quantity of memory cells refreshed in response to the refresh commands (e.g., controller adjusting row multiplier). In some cases, while in the second mode, the memory device may continue to receive and respond to refresh commands from the host device, while addressing the operative threshold not being satisfied by host device by initiating internal mechanisms (e.g., catch-up, self-refresh, or the like) to ensure that the operative threshold is satisfied.

In addition to entering a second mode of operation, the memory device may transmit signaling to the host device indicating that memory array has entered the second mode of operation. In some cases, the indication may include information that access to the memory device has changed. For example, the memory device may transmit information to the host device that mission mode or access commands (e.g., read, write, refresh) have been restricted (e.g., will be blocked, ignored, etc.). In some cases, the memory device may indicate to the host device that access has been restricted by sending a flag, a refresh threshold, or the like, or a combination thereof to the host device. For example, the memory device may send a flag to the host device to indicate that mission mode or access commands (e.g., read, write, refresh, etc.) are locked.

Additionally or alternatively, the host device may still be able to access a limited set of information from the memory device. For example, information related to the operative threshold, the refresh rate, or the like may be stored (e.g., in mode registers at the memory device) for access by the host device. Thus, upon receiving the indication, the host device may read one or more registers of the memory device that may include information related to the threshold, refresh rate, temperature, or the like. In some cases, the host device may use this information to modify or correct the refresh rate or to determine a response to the signaling received form the memory device (e.g., signaling indicating that the memory device has switch to a second mode of operation).

At block 525, the memory device may identify whether an acknowledgement has been received from the host device in response to the memory device entering the second mode of operation. If no acknowledgment has been received from the host device, the memory device may proceed to block 530 and maintain the memory array in the second mode of operation (e.g., safe mode). In some cases, the memory device may continue in the second mode of operation for a duration, which may be preconfigured or programmed by host device. For example, the memory device may continue in the second mode of operation for a duration (e.g., time period or quantity of clock cycles), or until receiving a command from the host device to return to the first mode (e.g., mission mode or access mode).

If an acknowledgement (or in some cases, a command to exit the second mode and/or reset to the first mode) is received from the host device, the memory array may proceed to block 535 and may exit the second mode of operation. In some cases, a reset procedure may transition the memory array from the second mode of operation (e.g., safe mode) to the first mode of operation (e.g., a mission mode or access mode). The command to reset to the first mode may include a single command (e.g., acknowledgement), or a specific indication (e.g., the operative threshold) that may be known by the host device and by the memory device. The sequence may act as an acknowledgement.

In some cases, the command to reset to the first mode of operation may include the host device sending a plurality of refresh commands to the memory device that satisfy the operative threshold. The memory device may monitor a refresh rate associated with these refresh commands, to determine if the operative threshold is satisfied. Upon determining that the operative threshold is satisfied, refresh detection circuit 335 may signal the controller to exit the second mode of operation.

At block 535, the controller may exit the second mode of operation in a variety of ways. A reset procedure may transition the memory array from the second mode of operation to the first mode of operation. When the memory device has determined that the reset operation has been executed, the memory device may proceed to block 505, where the memory device may operate in the first mode (e.g., mission mode or accesses mode).

In some cases, at block 535, the memory device may unlock a limited set of command options in response to receiving an acknowledgement from the host device at block 525. For example, the memory device may receive, process or carry out refresh commands to determine whether the host device is able to satisfy the operative threshold. The memory device may maintain a limited command set until the host device satisfies the operative threshold for one or more refresh cycles, upon which the memory may transition to block 505 and a full set of mode registry commands or access mode commands may be unlocked.

FIG. 6 shows a block diagram 600 of a device 605 that supports refresh rate management for a memory device as disclosed herein. The device 605 may be an example of aspects of a memory device—including aspects of a controller, a memory interface, a refresh detection circuit, or a threshold storage—as described herein. The device 605 may include a refresh command component 610, a threshold determination component 615, a threshold signaling component 620, a mode switching component 625, and a safe-mode operation component 630. Each of these modules may communicate, directly or indirectly, with one another (e.g., via one or more buses).

The refresh command component 610 may receive, from a host device, a set of refresh commands for a memory array. In some examples, the refresh command component 610 may receive, from the host device and after receiving the set of refresh commands for the memory array, an additional refresh command for the memory array. In some examples, the refresh command component 610 may receive, from the host device, a second set of refresh commands for the memory array. In some examples, the refresh command component 610 may determine a quantity of refresh commands included in the set of refresh commands, where the set of refresh commands are received during a timespan.

The threshold determination component 615 may determine that a refresh rate associated with the set of refresh commands is below a threshold that is based on a condition of the memory array. In some examples, the threshold determination component 615 may determine at least one of an extent to which the refresh rate associated with the set of refresh commands is below the threshold, or a duration of time for which the refresh rate associated with the set of refresh commands is below the threshold, or both. In some examples, the threshold determination component 615 may determine the threshold based on the temperature of the memory array. In some examples, the threshold determination component 615 may compare the determined quantity to a minimum quantity of refresh commands for the timespan, where determining that the refresh rate associated with the set of refresh commands is below the threshold is based on the comparing. In some examples, the threshold determination component 615 may determine that a second refresh rate associated with the second set of refresh commands satisfies the threshold.

The threshold signaling component 620 may transmit, to the host device, signaling that indicates that the refresh rate associated with the set of refresh commands is below the threshold. In some cases, the signaling transmitted to the host device includes an indication of a minimum refresh rate for the memory array. In some examples, the refresh command component 610 may receive, from the host device, an acknowledgement of the signaling that indicates that the refresh rate associated with the set of refresh commands is below the threshold.

The mode switching component 625 may switch the memory array from a first mode of operation to a second mode of operation based on determining that the refresh rate associated with the set of refresh commands is below the threshold. In some examples, the mode switching component 625 may restrict access to at least a portion of the memory array based on switching to the second mode of operation. In some examples, the mode switching component 625 may switch the memory array from the second mode of operation to the first mode of operation based on receiving the acknowledgement. In some examples, the mode switching component 625 may switch the memory array from the second mode of operation to the first mode of operation based on determining that the second refresh rate satisfies the threshold. In some examples, the mode switching component 625 may receive, from the host device, a command to switch the memory array from the second mode of operation to the first mode of operation. In some examples, the mode switching component 625 may switch the memory array from the second mode of operation to the first mode of operation based on receiving the command. In some examples, the mode switching component 625 may transmit, to the host device and based on switching the memory array from the second mode of operation to the first mode of operation, signaling that indicates that the memory array is in the first mode of operation.

The safe-mode operation component 630 may operate at least a portion of the memory array in a self-refresh mode based on mode switching component 625 switching the memory array to the second mode of operation. In some examples, the safe-mode operation component 630 may refresh a quantity of rows of the memory array based on receiving the additional refresh command, the quantity of rows based on (e.g., increased based on) determining that the refresh rate associated with the set of refresh commands is below the threshold.

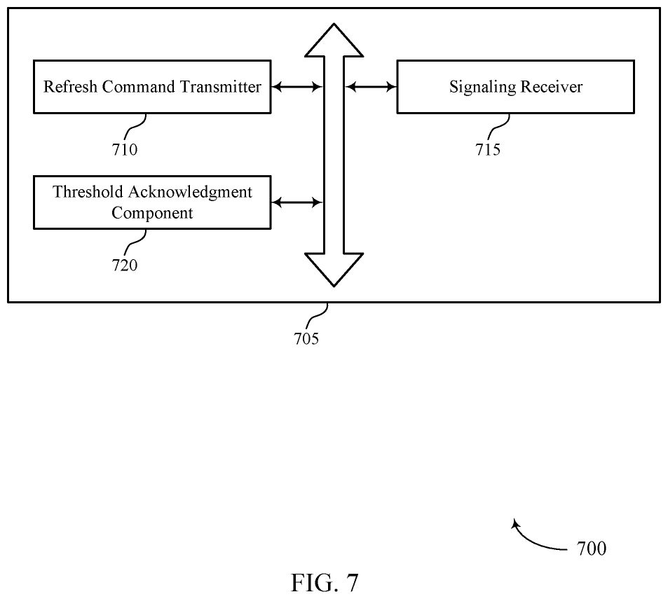

FIG. 7 shows a block diagram 700 of a device 705 that supports refresh rate management for a memory device as disclosed herein. The device 705 may be an example of aspects of a host device—including aspects of an external memory controller, a processor, a BIOS component, a peripheral component, or an I/O controller—as described herein. The device 705 may include a refresh command transmitter 710, a signaling receiver 715, and a threshold acknowledgment component 720. Each of these modules may communicate, directly or indirectly, with one another (e.g., via one or more buses).

The refresh command transmitter 710 may transmit, to a memory device, a set of refresh commands. In some examples, the refresh command transmitter 710 may transmit, to the memory device and within the duration, a second set of refresh commands including at least the quantity of refresh commands.

The signaling receiver 715 may receive, from the memory device, an indication that a refresh rate associated with the set of refresh commands is below a threshold. In some examples, the signaling receiver 715 may receive, from the memory device, an indication of a duration for receiving a quantity of refresh commands. In some examples, the signaling receiver 715 may receive, from the memory device, an indication that the memory device is in a mode of operation based on the refresh rate associated with the set of refresh commands being below the threshold.

The threshold acknowledgment component 720 may transmit, to the memory device, signaling based on receiving the indication that the refresh rate associated with the set of refresh commands is below the threshold. In some cases, the signaling transmitted to the memory device includes at least one of an acknowledgement of the indication that the refresh rate associated with the set of refresh commands is below the threshold, a command for the memory device to change a mode of operation of the memory device, or a second set of refresh commands for the memory device associated with a second refresh rate that is greater than the refresh rate associated with the set of refresh commands, or any combination thereof.

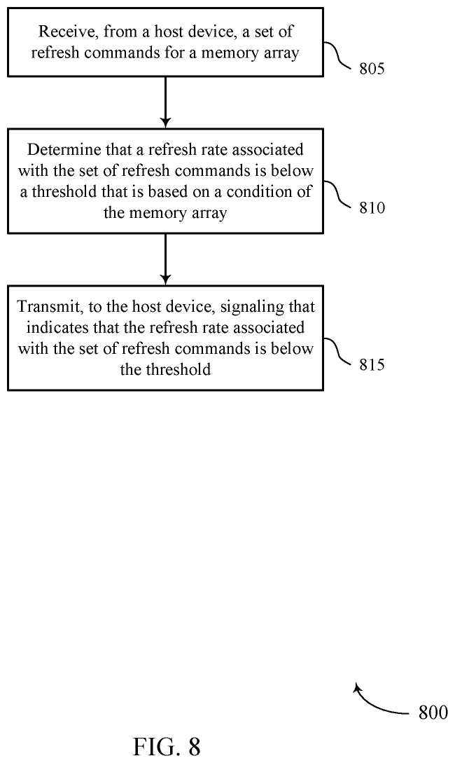

FIG. 8 shows a flowchart illustrating a method 800 that supports refresh rate management for a memory device as disclosed herein. The operations of method 800 may be implemented by a memory device or its components as described herein. For example, the operations of method 800 may be performed by circuitry as described herein. In some examples, the memory device may execute a set of instructions to control the functional elements of the memory device to perform the functions described herein. Additionally or alternatively, a memory device may perform aspects of the functions described herein using special-purpose hardware.

At 805, the memory device may receive, from a host device, a set of refresh commands for a memory array. The operations of 805 may be performed according to the methods described herein. In some examples, aspects of the operations of 805 may be performed by a refresh command component as described with reference to FIG. 6.

At 810, the memory device may determine that a refresh rate associated with the set of refresh commands is below a threshold that is based on a condition of the memory array. The operations of 810 may be performed according to the methods described herein. In some examples, aspects of the operations of 810 may be performed by a threshold determination component as described with reference to FIG. 6.

At 815, the memory device may transmit, to the host device, signaling that indicates that the refresh rate associated with the set of refresh commands is below the threshold. The operations of 815 may be performed according to the methods described herein. In some examples, aspects of the operations of 815 may be performed by a threshold signaling component as described with reference to FIG. 6.

In some examples, an apparatus as described herein may perform a method or methods, such as the method 800. The apparatus may include features, means, or instructions (e.g., a non-transitory computer-readable medium storing instructions executable by a processor) for receiving, from a host device, a set of refresh commands for a memory array, determining that a refresh rate associated with the set of refresh commands is below a threshold that is based on a condition of the memory array, and transmitting, to the host device, signaling that indicates that the refresh rate associated with the set of refresh commands is below the threshold.

Some examples of the method, apparatuses, and non-transitory computer-readable medium described herein may further include operations, features, means, or instructions for switching the memory array from a first mode of operation to a second mode of operation based on determining that the refresh rate associated with the set of refresh commands is below the threshold.

Some examples of the method, apparatuses, and non-transitory computer-readable medium described herein may further include operations, features, means, or instructions for restricting access to at least a portion of the memory array based on switching to the second mode of operation.

Some examples of the method, apparatuses, and non-transitory computer-readable medium described herein may further include operations, features, means, or instructions for operating at least a portion of the memory array in a self-refresh mode based on switching to the second mode of operation.

Some examples of the method, apparatuses, and non-transitory computer-readable medium described herein may further include operations, features, means, or instructions for receiving, from the host device, an acknowledgement of the signaling that indicates that the refresh rate associated with the set of refresh commands may be below the threshold.

Some examples of the method, apparatuses, and non-transitory computer-readable medium described herein may further include operations, features, means, or instructions for switching the memory array from the second mode of operation to the first mode of operation based on receiving the acknowledgement.

Some examples of the method, apparatuses, and non-transitory computer-readable medium described herein may further include operations, features, means, or instructions for receiving, from the host device, a second set of refresh commands for the memory array, determining that a second refresh rate associated with the second set of refresh commands satisfies the threshold, and switching the memory array from the second mode of operation to the first mode of operation based on determining that the second refresh rate satisfies the threshold.

Some examples of the method, apparatuses, and non-transitory computer-readable medium described herein may further include operations, features, means, or instructions for receiving, from the host device, a command to switch the memory array from the second mode of operation to the first mode of operation, and switching the memory array from the second mode of operation to the first mode of operation based on receiving the command.

Some examples of the method, apparatuses, and non-transitory computer-readable medium described herein may further include operations, features, means, or instructions for transmitting, to the host device and based on switching the memory array from the second mode of operation to the first mode of operation, signaling that indicates that the memory array may be in the first mode of operation.

Some examples of the method, apparatuses, and non-transitory computer-readable medium described herein may further include operations, features, means, or instructions for determining at least one of an extent to which the refresh rate associated with the set of refresh commands may be below the threshold, or a duration of time for which the refresh rate associated with the set of refresh commands may be below the threshold, or both, where.

Some examples of the method, apparatuses, and non-transitory computer-readable medium described herein may further include operations, features, means, or instructions for receiving, from the host device and after receiving the set of refresh commands for the memory array, an additional refresh command for the memory array, and refreshing a quantity of rows of the memory array based on receiving the additional refresh command, the quantity of rows based on determining that the refresh rate associated with the set of refresh commands may be below the threshold.

In some examples of the method, apparatuses, and non-transitory computer-readable medium described herein, the signaling transmitted to the host device includes an indication of a minimum refresh rate for the memory array.

In some examples of the method, apparatuses, and non-transitory computer-readable medium described herein, the condition of the memory array may include operations, features, means, or instructions for determining the threshold based on the temperature of the memory array.

Some examples of the method, apparatuses, and non-transitory computer-readable medium described herein may further include operations, features, means, or instructions for determining a quantity of refresh commands included in the set of refresh commands, where the set of refresh commands may be received during a timespan, and comparing the determined quantity to a minimum quantity of refresh commands for the timespan, where determining that the refresh rate associated with the set of refresh commands may be below the threshold may be based on the comparing.

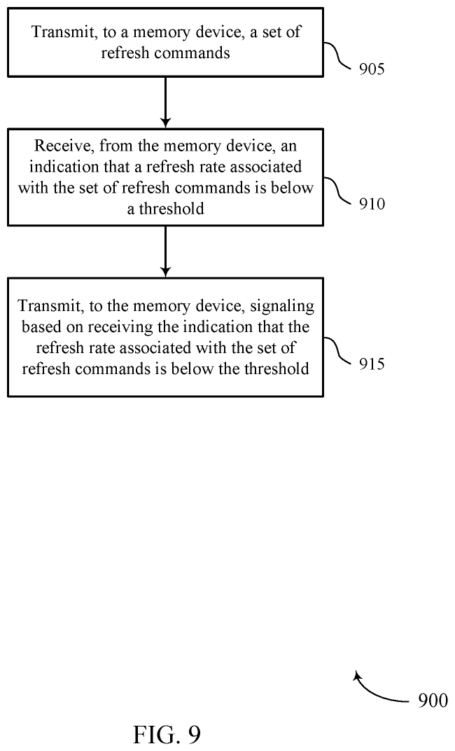

FIG. 9 shows a flowchart illustrating a method 900 that supports refresh rate management for a memory device as disclosed herein. The operations of method 900 may be implemented by a host device or its components as described herein. For example, the operations of method 900 may be performed by a circuitry as described with reference herein. In some examples, a host device may execute a set of instructions to control the functional elements of the host device to perform the functions described herein Additionally or alternatively, a host device may perform aspects of the functions described herein using special-purpose hardware.

At 905, the host device may transmit, to a memory device, a set of refresh commands. The operations of 905 may be performed according to the methods described herein. In some examples, aspects of the operations of 905 may be performed by a refresh command transmitter as described with reference to FIG. 7.

At 910, the host device may receive, from the memory device, an indication that a refresh rate associated with the set of refresh commands is below a threshold. The operations of 910 may be performed according to the methods described herein. In some examples, aspects of the operations of 910 may be performed by a signaling receiver as described with reference to FIG. 7.

At 915, the host device may transmit, to the memory device, signaling based on receiving the indication that the refresh rate associated with the set of refresh commands is below the threshold. The operations of 915 may be performed according to the methods described herein. In some examples, aspects of the operations of 915 may be performed by a threshold acknowledgment component as described with reference to FIG. 7.

In some examples, an apparatus as described herein may perform a method or methods, such as the method 900. The apparatus may include features, means, or instructions (e.g., a non-transitory computer-readable medium storing instructions executable by a processor) for transmitting, to a memory device, a set of refresh commands, receiving, from the memory device, an indication that a refresh rate associated with the set of refresh commands is below a threshold, and transmitting, to the memory device, signaling based on receiving the indication that the refresh rate associated with the set of refresh commands is below the threshold.

Some examples of the method, apparatuses, and non-transitory computer-readable medium described herein may further include operations, features, means, or instructions for receiving, from the memory device, an indication of a duration for receiving a quantity of refresh commands, and transmitting, to the memory device and within the duration, a second set of refresh commands including at least the quantity of refresh commands.

Some examples of the method, apparatuses, and non-transitory computer-readable medium described herein may further include operations, features, means, or instructions for receiving, from the memory device, an indication that the memory device may be in a mode of operation based on the refresh rate associated with the set of refresh commands being below the threshold.

In some examples of the method, apparatuses, and non-transitory computer-readable medium described herein, the signaling transmitted to the memory device includes at least one of an acknowledgement of the indication that the refresh rate associated with the set of refresh commands may be below the threshold, a command for the memory device to change a mode of operation of the memory device, or a second set of refresh commands for the memory device associated with a second refresh rate that may be greater than the refresh rate associated with the set of refresh commands, or any combination thereof.

It should be noted that the methods described herein describe possible implementations, and that the operations and the steps may be rearranged or otherwise modified and that other implementations are possible. Furthermore, aspects from two or more of the methods may be combined.

In some examples, an apparatus or device may perform aspects of the functions described herein using general- or special-purpose hardware. The apparatus or device may include a memory array having a set of rows of memory cells, a temperature sensor configured to determine a temperature of the memory array, a memory interface coupled with the memory array and a host, the memory interface configured to receive a set of commands for refreshing the memory array from the host, and circuitry coupled with the memory array and the memory interface. The circuitry may be operable to cause the apparatus to identify a target refresh rate of the memory array based at least in part on the temperature of the memory array, determine that a refresh rate associated with the commands for refreshing the memory array does not satisfy the target refresh rate, and transmit, to a host device coupled with the apparatus, signaling that indicates that the refresh rate associated with the set of commands does not satisfy the target refresh rate.

In some examples, the circuitry may operate the memory array in a safe mode based on determining that the refresh rate associated with the set of commands does not satisfy the target refresh rate.

Information and signals described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof. Some drawings may illustrate signals as a single signal; however, it will be understood by a person of ordinary skill in the art that the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some cases, the flow of signals between the connected components may be interrupted for a time, for example, using one or more intermediate components such as switches or transistors.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components, the controller affects a change that prevents signals from flowing between the components using a conductive path that previously permitted signals to flow.

The devices discussed herein, including a memory array, may be formed on a semiconductor substrate, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are signals), then the FET may be referred to as a n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” when a voltage greater than or equal to the transistor's threshold voltage is applied to the transistor gate. The transistor may be “off” or “deactivated” when a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to providing an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

Information and signals described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The various illustrative blocks and modules described in connection with the disclosure herein may be implemented or performed with a general-purpose processor, a DSP, an ASIC, an FPGA or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

The functions described herein may be implemented in hardware, software executed by a processor, firmware, or any combination thereof. If implemented in software executed by a processor, the functions may be stored on or transmitted over as one or more instructions or code on a computer-readable medium. Other examples and implementations are within the scope of the disclosure and appended claims. For example, due to the nature of software, functions described herein can be implemented using software executed by a processor, hardware, firmware, hardwiring, or combinations of any of these. Features implementing functions may also be physically located at various positions, including being distributed such that portions of functions are implemented at different physical locations. Also, as used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, digital subscriber line (DSL), or wireless technologies such as infrared, radio, and microwave are included in the definition of medium. Disk and disc, as used herein, include CD, laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

What is claimed is:

1. A method, comprising:
receiving, from a host device, a plurality of refresh commands for a memory array;
determining that a refresh rate associated with the plurality of refresh commands is below a threshold that is based at least in part on a condition of the memory array; and
transmitting, to the host device, signaling that indicates that the refresh rate associated with the plurality of refresh commands is below the threshold.

2. The method of claim 1, further comprising:
switching the memory array from a first mode of operation to a second mode of operation based at least in part on determining that the refresh rate associated with the plurality of refresh commands is below the threshold.

3. The method of claim 2, further comprising:
restricting access to at least a portion of the memory array based at least in part on switching to the second mode of operation.

4. The method of claim 2, further comprising:
operating at least a portion of the memory array in a self-refresh mode based at least in part on switching to the second mode of operation.

5. The method of claim 2, further comprising:
receiving, from the host device, an acknowledgement of the signaling that indicates that the refresh rate associated with the plurality of refresh commands is below the threshold.

6. The method of claim 5, further comprising:
switching the memory array from the second mode of operation to the first mode of operation based at least in part on receiving the acknowledgement.

7. The method of claim 2, further comprising:
receiving, from the host device, a second plurality of refresh commands for the memory array;
determining that a second refresh rate associated with the second plurality of refresh commands satisfies the threshold; and
switching the memory array from the second mode of operation to the first mode of operation based at least in part on determining that the second refresh rate satisfies the threshold.

8. The method of claim 2, further comprising:
receiving, from the host device, a command to switch the memory array from the second mode of operation to the first mode of operation; and
switching the memory array from the second mode of operation to the first mode of operation based at least in part on receiving the command.

9. The method of claim 8, further comprising:
transmitting, to the host device and based at least in part on switching the memory array from the second mode of operation to the first mode of operation, signaling that indicates that the memory array is in the first mode of operation.

10. The method of claim 2, further comprising:
determining at least one of an extent to which the refresh rate associated with the plurality of refresh commands is below the threshold, or a duration of time for which the refresh rate associated with the plurality of refresh commands is below the threshold, or both, wherein:
switching the memory array from the first mode of operation to the second mode of operation is based at least in part on at least one of determining the extent, or determining the duration of time, or both.

11. The method of claim 1, further comprising:
receiving, from the host device and after receiving the plurality of refresh commands for the memory array, an additional refresh command for the memory array; and
refreshing a quantity of rows of the memory array based at least in part on receiving the additional refresh command, the quantity of rows based at least in part on determining that the refresh rate associated with the plurality of refresh commands is below the threshold.

12. The method of claim 1, wherein the signaling transmitted to the host device comprises an indication of a minimum refresh rate for the memory array.

13. The method of claim 1, wherein the condition of the memory array comprises a temperature of the memory array, the method further comprising:
determining the threshold based at least in part on the temperature of the memory array.

14. The method of claim 1, further comprising:
determining a quantity of refresh commands included in the plurality of refresh commands, wherein the plurality of refresh commands are received during a timespan; and
comparing the determined quantity to a minimum quantity of refresh commands for the timespan, wherein determining that the refresh rate associated with the plurality of refresh commands is below the threshold is based at least in part on the comparing.

15. A method, comprising:
transmitting, to a memory device, a plurality of refresh commands;
receiving, from the memory device, an indication that a refresh rate associated with the plurality of refresh commands is below a threshold; and
transmitting, to the memory device, signaling based at least in part on receiving the indication that the refresh rate associated with the plurality of refresh commands is below the threshold.

16. The method of claim 15, further comprising:
receiving, from the memory device, an indication of a duration for receiving a quantity of refresh commands; and
transmitting, to the memory device and within the duration, a second plurality of refresh commands comprising at least the quantity of refresh commands.

17. The method of claim 15, further comprising:
receiving, from the memory device, an indication that the memory device is in a mode of operation based at least in part on the refresh rate associated with the plurality of refresh commands being below the threshold.

18. The method of claim 15, wherein the signaling transmitted to the memory device comprises at least one of an acknowledgement of the indication that the refresh rate associated with the plurality of refresh commands is below the threshold, a command for the memory device to change a mode of operation of the memory device, or a second plurality of refresh commands for the memory device associated with a second refresh rate that is greater than the refresh rate associated with the plurality of refresh commands, or any combination thereof.

19. An apparatus, comprising:
a memory array having a plurality of rows of memory cells;
a temperature sensor configured to determine a temperature of the memory array;
a memory interface coupled with the memory array and a host, the memory interface configured to receive a plurality of commands for refreshing the memory array from the host; and
circuitry coupled with the memory array and the memory interface, the circuitry operable to cause the apparatus to:
identify a target refresh rate of the memory array based at least in part on the temperature of the memory array;
determine that a refresh rate associated with the plurality of commands for refreshing the memory array does not satisfy the target refresh rate; and
transmit, to a host device coupled with the apparatus, signaling that indicates that the refresh rate associated with the plurality of commands does not satisfy the target refresh rate.

20. The apparatus of claim 19, wherein the circuitry is further operable to cause the apparatus to:
operate the memory array in a safe mode based at least in part on determining that the refresh rate associated with the plurality of commands does not satisfy the target refresh rate.
